(19) United States
(12) Patent Application Publication
(10) Pub. No.: US 2014/0028379 A1
(43) Pub. Date: Jan. 30, 2014

(54) SINGLE-LAYER CAPACITIVE TOUCH-CONTROL PANEL APPARATUS

(71) Applicant: ILI TECHNOLOGY CORP., HSINCHU COUNTY (TW)

(72) Inventors: MING-CHUNG CHANG, HSINCHU CITY (TW); JIM HSU, HSINCHU COUNTY (TW)

(73) Assignee: ILI TECHNOLOGY CORP., HSINCHU COUNTY (TW)

(21) Appl. No.: 13/747,570

(22) Filed: Jan. 23, 2013

(30) Foreign Application Priority Data
Jul. 27, 2012 (CN) 201210265573.8

(51) Int. Cl. H03K 17/96

(52) U.S. Cl. CPC H03K 17/9622
USPC 327/517

(57) ABSTRACT

A single-layer capacitive touch-control panel apparatus is provided. The single-layer capacitive touch-control panel apparatus includes a touch-control substrate and a touch-control chip. The touch-control substrate has M touch areas, and each touch area of the plurality of the touch areas includes an axial body and N electrodes. The axial body is electrically connected to the touch-control chip through a first conductive line. N electrodes are disposed on the axial body and are electrically connected to the touch-control chip through a plurality of second conductive lines. The touch-control chip is disposed on the touch-control substrate of single-layer, wherein M [symbol] N are positive integer.

### BACKGROUND

1. Technical Field

The present invention relates to a touch-control panel; in particular, to single-layer capacitive touch-control panel.

2. Description of Related Art

With the advancement of the technology, the electronic information product is not only progressing toward a direction of being lighter and thinner, but also provides a more friendly human-machine interface so as to bring the convenience for the user. The human-machine interface includes an output interface and an input interface and the human-machine interface acts as a bridge between the user and electronic information product. The liquid crystal panel possesses some advantages, such as slim and light, such that it is easy for user to carry the liquid crystal panel, and the liquid crystal panel gradually replaces the cathode ray tube (CRT) commonly used for traditional output interface. With the use of liquid crystal panel, the input interface of traditional human-machine interface, such as a mouse and a keyboard, is replaced with a touch-control panel.

The capacitive touch-control panel is widely applied in the electronic information product due to the advantage of positioning precisely. The capacitive touch-control panel includes a plurality of sensing units arranged in array manner and the sensing chip electrically connected to the sensing units, wherein the sensing chip is used for sensing a touched state of the capacitive touch-control panel. A plurality of detecting signal lines are connected to each row or each column of the sensing units, and each of the plurality of detecting signal lines is connected to one end of each sensing unit located on each row or each column. When a finger touches any sensing unit, the touched sensing unit may generate a potential variation due to the effect of field coupling, and the sensing chip may acquire at least a touched location on the touch-control panel through detecting variation amounts of detecting signals transmitted by the detecting signal lines.

Because a size of liquid crystal screen is getting larger, a resolution of the capacitive touch-control panel thus increases correspondingly, such that more accurate positioning is provided. In other words, for the liquid crystal screen with large size, the capacitive touch-control panel should have a larger sensing unit array, and it means that a large amount of the detecting signal lines should be utilized in the capacitive touch-control panel to transmit the sensing signals outputted by the sensing units. In related art, the sensing chip is electrically connected to each row or each column of sensing unit array of liquid crystal panel through a flexible printed circuit (FPC) board, and the large amount of the detecting signal lines may represent a fact that it needs the sensing chip with more channels and the FPC with larger area. However, it may increase cost of the sensing chip and FPC and increase difficulty for circuit layout on the capacitive touch-control panel.

### SUMMARY OF THE INVENTION

The present invention provides a single-layer capacitive touch-control panel apparatus. The single-layer capacitive touch-control panel apparatus includes a touch-control chip and a touch-control substrate. The touch-control substrate has M touch-control areas which are parallel to a first direction and insulate from each other, wherein M is a positive integer and each touch-control area comprises an axial body and N electrodes. The axial body is electrically connected to the touch-control chip through a first conductive line. The N electrodes are disposed on the axial body and are electrically connected to the touch-control chip through a plurality of second conductive lines, wherein the first conductive lines electrically connected to each touch-control area and the plurality of second conductive lines does not intersect, and the electrodes and the axial body generates effect of mutual capacitance, wherein N is positive integer, wherein the touch-control chip is disposed on the single-layer touch-control substrate.

In an embodiment of the present invention, wherein the touch-control chip is disposed on the single-layer touch-control substrate with a substrate technology of the chip on glass.

In an embodiment of the present invention, wherein the touch-control chip comprises a first touch control circuit. The first touch control circuit sequentially transmits a plurality of the driving scan signal to the axial bodies through the first conductive lines according to a plurality of predetermined scanning time, wherein the plurality of predetermined scanning time are corresponding to the touch-control areas sequentially.

In an embodiment of the present invention, when voltage of at least one of the electrodes changes, the first touch control circuit acquires a coordinate of at least one touch-point according to voltage variation of each touch-control signal in the second conductive lines and the touch-control areas corresponding to the plurality of predetermined scanning time.

In summary, the single-layer capacitive touch-control panel apparatus, provided by the embodiments of the instant disclosure, makes the touch-control chip be disposed on the single-layer capacitive touch-control panel apparatus. Accordingly, the present disclosure may not only significantly reduce a space occupied by the conventional flexible printed circuit board, but also reduce a cost for package.

For further understanding of the present invention, reference is made to the following detailed description illustrating the embodiments and examples of the present invention. The description is only for illustrating the present invention, not for limiting the scope of the claim.

### BRIEF DESCRIPTION OF THE DRAWINGS

FIG. 1 shows a schematic diagram of the single-layer capacitive touch-control apparatus according to one embodiment of the present disclosure;

FIG. 2 shows a driving waveform diagram of the driving scan signal according to one embodiment of the present disclosure;

FIG. 3A shows a schematic diagram of the single-layer capacitive touch-control apparatus according to another one embodiment of the present disclosure;

FIG. 3B shows a driving waveform diagram of the driving scan signal according to another one embodiment of the present disclosure;

FIG. 4 shows a detailed schematic diagram of the single-layer capacitive touch control apparatus, according to one embodiment of the present disclosure; and

FIG. 5 shows a detailed schematic diagram of the single-layer capacitive touch-control apparatus according to one embodiment of the present disclosure.

### DETAILED DESCRIPTION OF PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings. In the drawings, the size and relative sizes of layers and regions may be exaggerated for clarity.

It will be understood that, although the terms first, second, third, and the like, may be used herein to describe various elements, components, regions, layers and/or sections, these elements, components, regions, layers and/or sections should not be limited by these terms. These terms are only to distinguish one element, component, region, layer or section from another region, layer or section discussed below could be termed a second element, component, region, layer or section without departing from the teachings of the present disclosure. As used herein, the term “and/or” includes any and all combinations of one or more of the associated listed items.

[Embodiment of the Single-Layer Capacitive Touch-Control Apparatus]

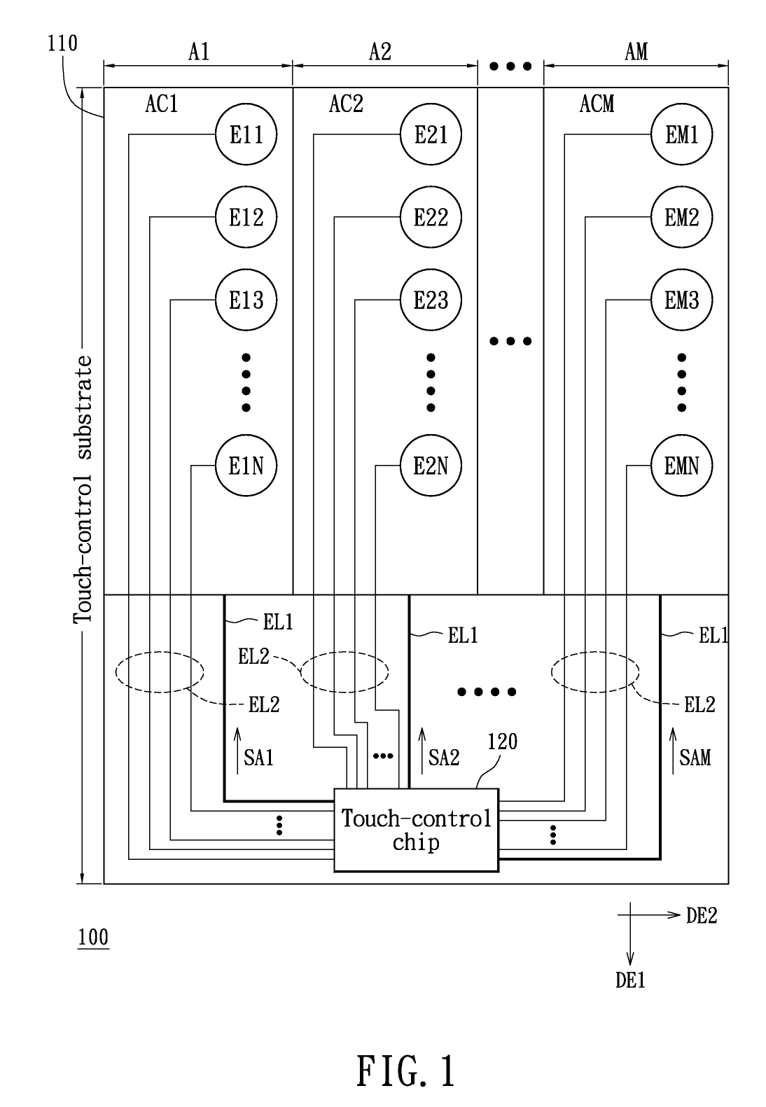

Referring to FIG. 1, FIG. 1 shows a schematic diagram of the single-layer capacitive touch-control apparatus according to one embodiment of the present disclosure. The single-layer capacitive touch-control apparatus 100 includes a touch-control substrate 101 and a touch-control chip 120, wherein the substrate of the single-layer capacitive touch-control apparatus is transparent insulating material, such as glass or polyethylene. The touch-control substrate 110 has M touch-control areas A1˜AM which are parallel to a first direction DE1 and insulate from each other. A first touch-control area A1 among the M touch-control areas A1˜AM includes an axial body AC1 and N electrodes E11˜E1N, a second touch-control area A2 among the M touch-control areas A1˜AM includes an axial body AC2 and N electrodes E21˜E2N, and similarly, a touch-control area AM among the M touch-control areas A1˜AM includes an axial body ACM and N electrodes EM1˜EMN, wherein M [symbol] N is positive integer. In other words, the touch-control substrate 110 is formed with the axial bodies AC1˜ACM and the electrodes E11˜EMN.

Each of the axial bodies AC1˜ACM is electrically connected to the touch-control chip 120 respectively through one of a plurality of first conductive lines EL1. For example, the electrodes E11˜E1N are disposed on the axial body AC1 corresponding to the axial bodies AC1˜ACM, the electrodes E11˜E2N are disposed on the axial body AC2 corresponding to the axial bodies AC1˜ACM, and similarly, the electrodes EM1˜EMN are disposed on the axial body ACM corresponding to the axial bodies AC1˜ACM. The electrodes E11˜EMN are electrically connected to the touch-control chip 120 respectively through a plurality of second conductive lines.

Moreover, the first conductive line EL1 of each of the touch-control areas A1˜AM and the second conductive lines EL2 does not intersect each other and the electrodes (e.g. E11˜E1N, E21˜E2N, . . . , EM1˜EMN) and the corresponding axial bodies (e.g. AC1˜ACM) thereof may generate effect of mutual capacitance. In other words, the electrodes E11˜E1N and the corresponding axial body AC1 thereof may generate effect of mutual capacitance, the electrodes E21˜E2N and the corresponding axial body AC2 thereof may generate effect of mutual capacitance, and similarly, the electrodes EM1˜EMN and the corresponding axial body ACM thereof may generate effect of mutual capacitance.

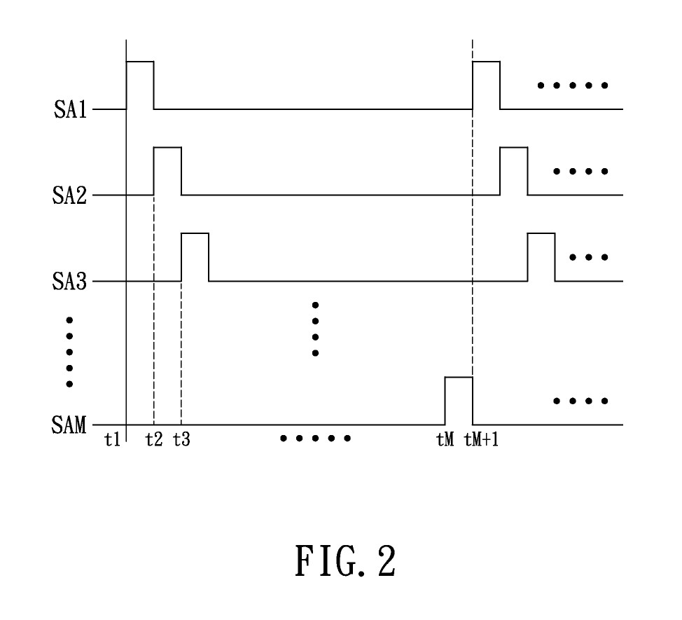

Referring to FIG. 1 and FIG. 2, FIG. 2 shows a driving waveform diagram of the driving scan signal according to one embodiment of the present disclosure. The touch-control chip 120 sequentially transmits a plurality of driving scan signals SA1˜SAM to the corresponding axial body AC1˜ACM through the first conductive lines EL1 according to a plurality of predetermined scanning time t1˜tM. In other words, at the predetermined scanning time t1, the touch-control chip 120 transmits the driving scan signal SA1 to the corresponding axial body AC1 through the first conductive line EL1; and at the predetermined scanning time t2, the touch-control chip 120 transmits the driving scan signal SA2 to the corresponding axial body AC2 through the first conductive line EL1. Similarly, at the predetermined scanning time tM, the touch-control chip 120 transmits the driving scan signal SAM to the corresponding axial body ACM through the first conductive line EL1. Accordingly, the touch-control chip 120 may sense the coordinate of the touch point through scanning the whole capacitive touch-control panel.

When the voltage of at least one of the electrodes E111˜EMN changes, the touch-control chip 120 may sense voltage variation of each touch-control signal in the second conductive lines EL2, and further acquire at least one coordinate of the touch point according to voltage variation of each touch-control signal in the second conductive lines EL2 and the touch-control areas A1˜AM corresponding to the predetermined scanning time t1˜tM. In short, the single-layer capacitive touch-control panel apparatus 100 of the instant disclosure not only senses single point touch-control, but also senses multi-point touch-control effectively.

For example, when the user utilize a finger or a touch-control pen to touch at least one electrode of the single-layer capacitive touch-control panel apparatus 100, such as the electrodes E22 and E56, the potential of the electrodes E22 and E56 may generate variation due to field coupling effect of the finger or the touch-control pen, so as to transmit the voltage variation of the touch-control signal of the electrodes E22 and E56 to the touch-control chip 120 through electrically connection between the second conductive lines EL2 and the touch-control chip 120.

Firstly, suppose a first direction DE1 is Y-axis and a second direction DE2 is X-axis hereinafter. The touch-control chip 120 may acquire the Y coordinates of the two touch points according to the relationship of electrically connection for electrodes E22 and E56 in the touch-control chip 120. The touch-control chip 120 may further acquire the X coordinates of the two touch points according to the predetermined scanning time t1˜tM, wherein the touch-control chip 120 transmits a plurality of driving scan signals SA1 SAM to the corresponding touch-control areas A1˜AM so as to drive the axial bodies AC1˜ACM respectively through the first conductive lines EL1 according to the plurality of predetermined scanning time t1˜tM. In other words, the touch-control chip 120 may transmit the driving scan signal SA2 to the touch-control area A2 at the predetermined scanning time t2 and sense the voltage variation of the touch-control signal of the electrode E22. The touch-control chip 120 may transmit the driving scan signal SA5 to the touch-control area A5 at the predetermined scanning time t5 and sense the voltage variation of the touch-control signal of the electrode E56. Therefore, the touch-control chip 120 may precisely position and acquire touch coordinate of the two touch point.

It is worth mentioning that the touch-control chip 120 of the present embodiment is disposed on the touch-control substrate 110, and in the exemplary embodiment, the touch-control chip 120 is disposed on or directly embedded into the touch-control substrate 110 with the technology of the chip on glass. In addition, in another one exemplary embodiment, the touch-control chip 120 is disposed on the touch-control substrate 110 by the means of the adhesion. It is to be noted that the means for the touch-control chip 120 disposed on the touch-control substrate 110 is not used for limiting the present disclosure. In short, without departing from the spirit of making the touch-control chip 120 be disposed on the touch-control substrate 110, the scope disclosed all belongs to the thoughts of technology of the present disclosure.

Additionally, in one of the embodiments, if the touch-control substrate 110 may serve as an outer shell protection glass for general electronic apparatus, it may save a manufacturing cost for the touch-control panel. In other words, it may integrate the touch-control panel layer and the outer shell protection layer into the same touch-control substrate 110. Accordingly, it may reduce the weight, thickness and manufacturing cost for the single-layer capacitive touch-control panel apparatus 110. It is worth mentioning that the aforementioned outer shell protection glass also may be other kind of outer shell protection layer with transparent and insulating characteristic.

Compared with the prior art, the single-layer capacitive touch-control panel apparatus 110 provided by the instant disclosure does not need the bridge connection and be capable of reducing at least one mask for lithography process, so as to significantly decrease the cost of circuit manufacturing and circuit design due to use touch-control substrate 110 with single layer. Moreover, because the touch-control chip 120 is disposed on the touch-control substrate, the present disclosure may significantly reduce the space occupied by the conventional flexible printed circuit board and further reduce a cost of the package.

In the follow-up embodiments, the instant disclosure will describe the part which is different from aforementioned embodiment of FIG. 1 and FIG. 2, and the components same as aforementioned embodiments of FIG. 1 and FIG. 2 are thus omitted. Furthermore, similar reference numeral or mark indicate similar reference device for ease of explanation.

[Another One Embodiment of the Single-Layer Capacitive Touch-Control Apparatus]

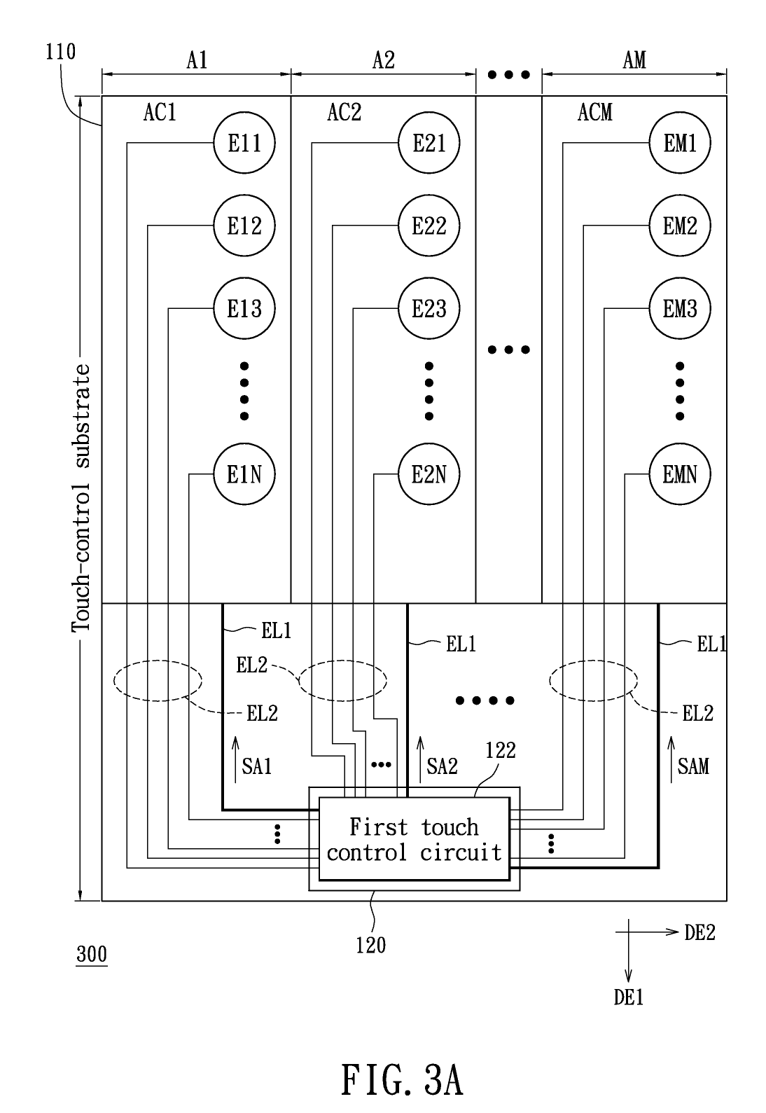

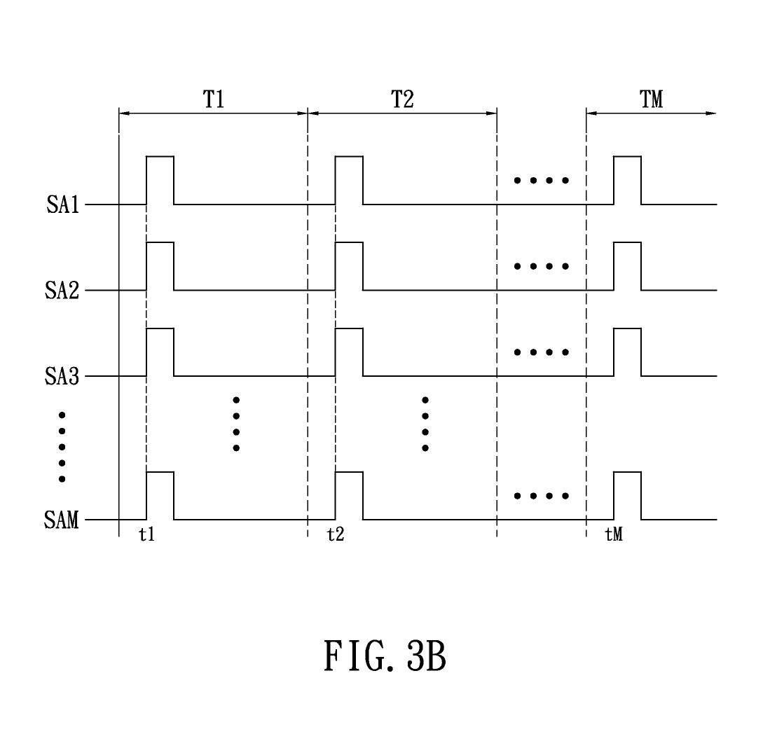

Referring to FIG. 3A, FIG. 3A shows a schematic diagram of the single-layer capacitive touch-control apparatus according to another one embodiment of the present disclosure. In this embodiment, the touch-control chip 120 of the single-layer capacitive touch-control apparatus 300 includes a first touch control circuit 122, wherein the first touch control circuit 122 is manufactured in the touch-control chip 120 with the technology of the integrated circuit, and this helps to make the touch-control chip 120 be disposed on the touch-control substrate 110 with single-layer.

Each of the axial bodies AC1˜ACM is electrically connected to the first touch control circuit 122 respectively through one of a plurality of first conductive lines EL1. N electrodes are disposed corresponding to the axial bodies AC1˜ACM. For example, the electrodes E11˜E1N is disposed on the axial body AC1, the electrodes E21˜E2N is disposed on the axial body AC2, and similarly, the electrodes EM1˜EMN is disposed on the axial body ACM. The electrodes E11˜EMN is electrically connected to the first touch control circuit 122 through a plurality of second conductive lines EL2 respectively.

Moreover, the first conductive line EL1 of each of the touch-control areas A1˜AM and the second conductive lines EL2 does not intersect each other, and the electrodes (e.g. E11˜E1N, E21˜E2N, . . . , EM1˜EMN) and the corresponding axial bodies (e.g. AC1˜ACM) thereof may generate effect of mutual capacitance. In other words, the electrodes E11˜E1N and the corresponding axial body AC1 thereof may generate effect of mutual capacitance, the electrodes E21˜E2N and the corresponding axial body AC2 thereof may generate effect of mutual capacitance, and similarly, the electrodes EM1˜EMN and the corresponding axial body ACM thereof may generate effect of mutual capacitance.

Referring to FIG. 2 and FIG. 3A at the same time, the first touch control circuit 122 sequentially transmits a plurality of driving scan signals SA1˜SAM to the corresponding axial body AC1˜ACM through the first conductive lines EL1 according to a plurality of predetermined scanning time t1˜tM. In other words, at the predetermined scanning time t1, the first touch control circuit 122 transmits the driving scan signal SA1 to the corresponding axial body AC1 through the first conductive line EL1; and at the predetermined scanning time t2, the first touch control circuit 122 transmits the driving scan signal SA2 to the corresponding axial body AC2 through the first conductive line EL1. Similarly, at the predetermined scanning time tM, the first touch control circuit 122 transmits the driving scan signal SAM to the corresponding axial body ACM through the first conductive line EL1. Accordingly, the first touch control circuit 122 may sense the coordinate of the touch point through scanning the whole single-layer capacitive touch-control panel.

When the voltage of at least one of the electrodes E11˜EMN changes, the first touch control circuit 122 may sense voltage variation of each touch-control signal in the second conductive lines EL2 and acquire at least one coordinate according to voltage variation of each touch-control signal in the second conductive lines EL2 and the touch-control areas corresponding to the predetermined scanning time t1˜tM. In other words, the first touch control circuit 122 may acquire Y coordinate of at least one touch point through the calculation of the touch signals of the second conductive lines EL2, and then the first touch control circuit 122 acquire X coordinate of at least one touch point through the touch-control areas A1˜AM corresponding to the predetermined scanning time t1˜tM.

In another one embodiment, referring to FIG. 3A and FIG. 3B, FIG. 3B shows a driving waveform diagram of the driving scan signal according to another one embodiment of the present disclosure. The first touch control circuit 122 transmits a plurality of driving scan signal SA1˜SAM to the corresponding axial bodies AC1˜ACM through the first conductive lines EL1 at the same time according to the predetermined scanning time t1˜tM in each of the scanning period T1˜TM. In other words, at the predetermined scanning time t1 of the scanning period T1, the first touch control circuit 122 transmits the plurality of driving scan signal SA1˜SAM to the corresponding axial bodies AC1˜ACM through the first conductive lines EL1 at the same time. At the predetermined scanning time t2 of the scanning period T2, the first touch control circuit 122 transmits the plurality of driving scan signal SA1˜SAM to the corresponding axial bodies AC1˜ACM through the first conductive lines EL1 at the same time. Similarly, at the predetermined scanning time tM of the scanning period TM, the first touch control circuit 122 transmits the plurality of driving scan signal SA1˜SAM to the corresponding axial bodies AC1˜ACM through the first conductive lines EL1 at the same time. Accordingly, in every scanning period T1˜TM, the first touch control circuit 122 may sense the coordinate of the touch point through scanning the whole capacitive touch-control panel at the same time.

When the voltage of at least one of the electrodes E11˜EMN changes, the first touch control circuit 122 may sense voltage variation of each touch-control signal in the second conductive lines EL2 and acquire at least one coordinate according to voltage variation of each touch-control signal in the second conductive lines EL2. Therefore, in the embodiment of FIG. 3A, the sensing and calculation method of the first touch control circuit 122 for the touch point may make co-ordination of design, according to the driving scan method for driving scan signal SA1˜SAM. The difference for driving scan method is not used for limiting the range of the technology thought for the present disclosure. In short, the single-layer capacitive touch-control panel apparatus of the instant disclosure not only senses single point touch-control, but also senses multi-point touch-control effectively.

What follows is further illustrating the detail of the capacitive touch-control panel apparatus.

[One Embodiment of the Single-Layer Capacitive Touch Control Apparatus]

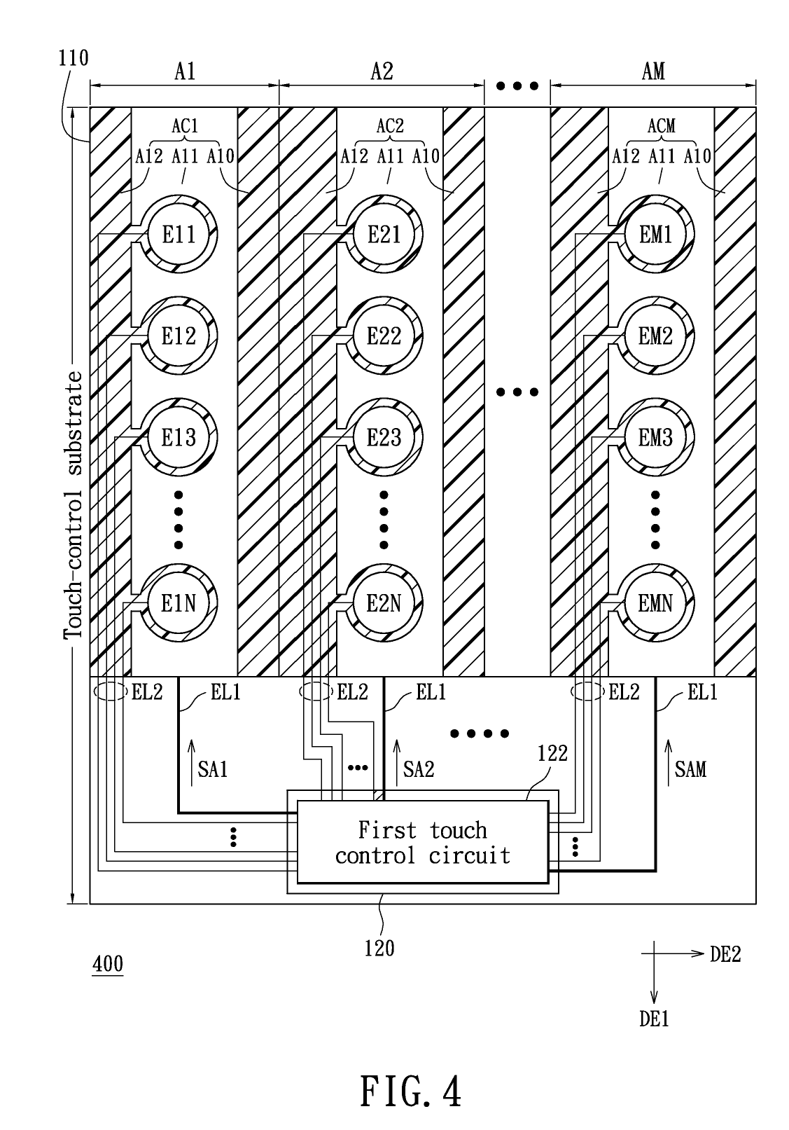

Referring to FIG. 4, FIG. 4 shows a detailed schematic diagram of the single-layer capacitive touch control apparatus, according to one embodiment of the present disclosure. Each of the axial bodies AC1˜ACM of the single-layer capacitive touch control apparatus 400 includes a first insulating area A10, a first conductive area A11 and a second insulating area A12.

The first conductive areas A11 are electrically connected to the first touch control circuit 122 through the corresponding first conductive line EL1.

The electrodes (e.g. E11˜E1N, E21˜E2N, . . . , EM1˜EMN) of each touch-control area are respectively disposed on the corresponding second insulating area A12. In other words, the electrodes E11˜E1N are disposed on the corresponding second insulating area A12 of the axial body AC1, the electrodes E21˜E2N are disposed on the corresponding second insulating area A12 of the axial body AC2, and similarly, the electrodes EM1˜EMN are disposed on the corresponding second insulating area A12 of the axial body ACM.

The electrodes (e.g. E11˜E1N, E21˜E2N, . . . , EM1˜EMN) are electrically connected to the first touch control circuit 122 respectively through the second conductive lines EL2, and it is worth to be noted that the second insulating area A12 is smaller than the first insulating area A10 in the present embodiment so as to distinguish the axial bodies AC1˜ACM, but the embodiment is not restricted thereto. In the present embodiment, the second conductive lines EL2 are disposed on the second insulating areas A12, and in another one embodiment, the second conductive lines EL2 are disposed on the first insulating areas A10, but the present embodiment is not restricted thereto. Moreover, when the first touch control circuit 130 transmits the plurality of driving scan signals SA1˜SAM to the corresponding first conductive area A11 respectively, the electrodes (e.g. E11˜E1N, E21˜E2N, . . . , EM1˜EMN) and the corresponding first conductive area A11 may generate mutual capacitance each other, wherein the driving scan signals SA1˜SAM may be transmitted sequentially (as shown in FIG. 2) or concurrently (as shown in FIG. 3B).

In other words, the electrodes E11˜E1N and the first conductive area A11 of the axial body AC1 may generate mutual capacitance, the electrodes E21˜E2N and the first conductive area A11 of the axial body AC2 may generate mutual capacitance, and similarly, the electrodes EM1˜EMN and the first conductive area A11 of the axial body ACM may generate mutual capacitance. Incidentally, in this embodiment, the material of the first conductive area A11 and the electrodes (e.g. E11˜E1N, E21˜E2N, . . . , EM1˜EMN) both are the transparent conductive film and the transparent conductive film may be an indium tin oxide (ITO), indium zinc oxide (IZO) or antimony tin oxide (ATO). The material of the first insulating area A10 and the second insulating area A12 is glass, polyethylene or a material with non-conductive and transparent characteristic.

In the embodiment of the instant disclosure, the touch-control substrate 110 of the single-layer capacitive touch-control panel apparatus 400 is divided into a plurality of touch-control areas A1˜AM through the first insulating area A10, and each of the axial bodies AC1˜ACM on the touch-control area is divided into the first insulating area A10, the first conductive area A11 and the second insulating area A12. Accordingly, the first touch control circuit 122 is capable of driving each of the touch-control area A1˜AM respectively, in other words, the first touch control circuit 122 transmits the plurality of driving scan signals SA1˜SAM to the corresponding first conductive areas A11 through the first conductive lines EL1 so as to drive each of the touch-control area A1˜AM, and then the single-layer capacitive touch-control panel apparatus 400 may sense coordinate of the touch point through scanning the whole capacitive touch-control panel.

In the follow-up embodiments, the instant disclosure will describe the part different from aforementioned embodiments of FIG. 4 and other ignoring part is the same as aforementioned embodiments of FIG. 4. Furthermore, similar reference numeral or mark indicate similar reference device for ease of explanation.

[One Embodiment of the Single-Layer Capacitive Touch-Control Apparatus]

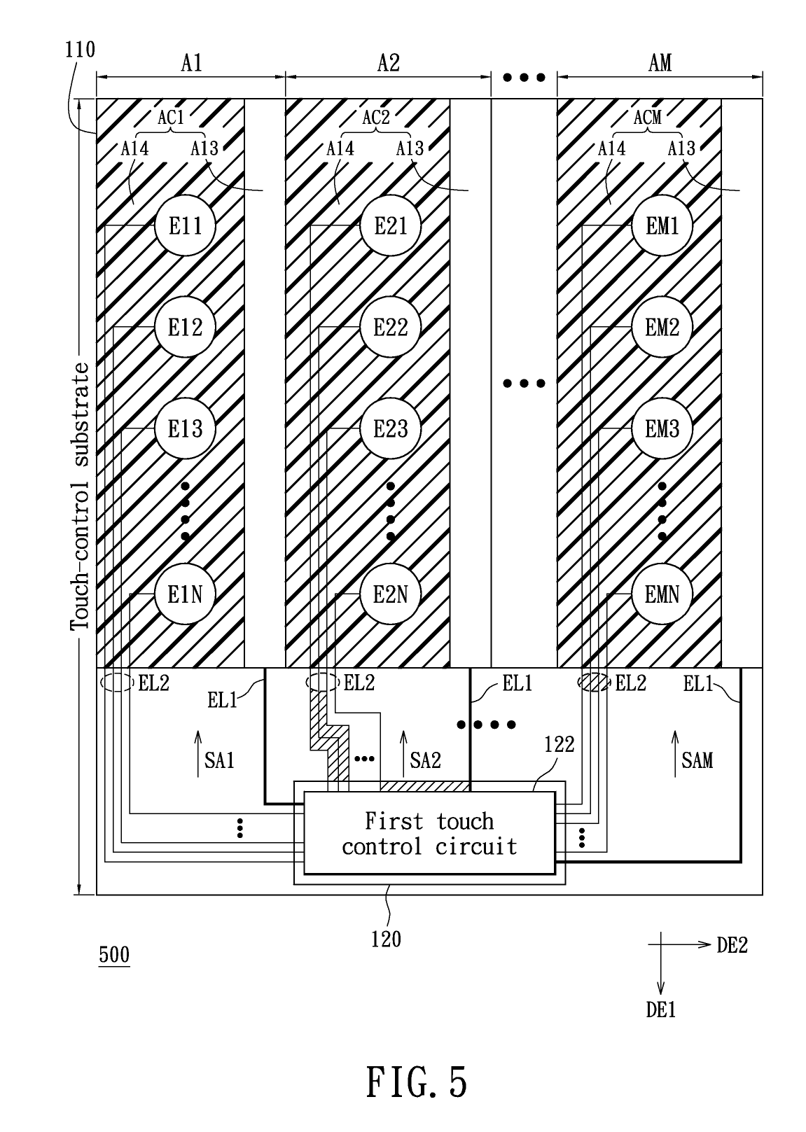

Referring to FIG. 5, FIG. 5shows a detailed schematic diagram of the single-layer capacitive touch-control apparatus according to one embodiment of the present disclosure. The difference compared with above-mentioned embodiment in FIG. 4 is that each of the axial bodies AC1˜ACM of the single-layer capacitive touch-control apparatus 500 includes a second conductive area A13 and the third insulating area A14.

The second conductive areas A13 are electrically connected to the first touch control circuit 122 respectively through the corresponding first conductive line EL1. The electrodes (e.g. E11˜E1N, E21˜E2N, . . . , EM1˜EMN) are respectively disposed within the third insulating area A14. In other words, the electrodes E11˜E1N are disposed within the third insulating area A14 of the axial body AC1, the electrodes E21˜E2N are disposed within the third insulating area A14 of the axial body AC2, and similarly, the electrodes EM1˜EMN are disposed within the third insulating area A14 of the axial body ACM.

Moreover, the electrodes (e.g. E11˜E1N, E21˜E2N, . . . , EM1˜EMN) are electrically connected to the first touch control circuit 122 through the second conductive lines EL2 respectively. In the each of the axial bodies AC1˜ACM, the second conductive line EL2 is disposed on the third insulating area A14. When the first touch control circuit 122 respectively transmits the plurality of driving scan signals SA1˜SAM to the corresponding second conductive area A13, the electrodes (e.g. E11˜E1N, E21˜E2N, . . . , EM1˜EMN) and the corresponding second conductive area A13 may generate mutual capacitance, wherein the driving scan signals SA1˜SAM may be transmitted sequentially (as shown in FIG. 2) or concurrently (as shown in FIG. 3B).

In other words, the electrodes E11˜E1N and the corresponding second conductive area A13 of the axial body AC1 may generate mutual capacitance, the electrodes E21˜E2N and the corresponding second conductive area A13 of the axial body AC2 may generate mutual capacitance, and similarly, the electrodes EM1˜EMN and the corresponding second conductive area A13 of the axial body ACM may generate mutual capacitance. Incidentally, in this embodiment, the material of the second conductive area A13 and the electrodes (e.g. E11˜E1N, E21˜E2N, . . . , EM1˜EMN) both are the transparent conductive film, and the transparent conductive film may be an indium tin oxide (ITO), indium zinc oxide (IZO) or antimony tin oxide (ATO). The material of the third insulating area A14 is glass, polyethylene or a material with non-conductive and transparent characteristic.

In the embodiment of the instant disclosure, the touch-control substrate 110 of the single-layer capacitive touch-control panel apparatus 500 is divided into a plurality of touch-control areas A1˜AM, and each of the axial bodies AC1˜ACM on the touch-control area is divided into the second conductive area A13 and the third insulating area A14. Therefore, the first touch control circuit 122 may be capable of driving each of the touch-control area A1˜AM, in other words, the first touch control circuit 122 transmits the plurality of driving scan signals SA1˜SAM to the corresponding second conductive areas A13 through the first conductive lines EL1 so as to drive each of the touch-control areas A1˜AM, and then the single-layer capacitive touch-control panel apparatus 500 may sense coordinate of the touch point through scanning the whole capacitive touch-control panel.

To sum up, the single-layer capacitive touch-control panel apparatus, provided by the embodiments of the instant disclosure, makes the touch-control chip be disposed on the single-layer capacitive touch-control panel apparatus. Accordingly, the present disclosure may not only significantly reduce a space occupied by the conventional flexible printed circuit board, but also reduce a cost for package.

In at least one of the embodiments of the instant disclosure, the touch-control substrate is an integrated touch-control substrate that is capable of integrating the touch-control panel layer and the outer shell protection layer into the same substrate.

In at least one of the embodiments of the instant disclosure, the single-layer capacitive touch-control panel apparatus does not need the bridge connection and be capable of reducing at least one mask for lithography process, so as to significantly decrease the cost of circuit manufacturing and circuit design due to use touch-control substrate 110 with single layer.

In at least one of the embodiments of the instant disclosure, the single-layer capacitive touch-control panel apparatus not only senses single point touch-control, but also senses multi-point touch-control effectively.

The descriptions illustrated supra set forth simply the preferred embodiments of the instant disclosure; however, the characteristics of the instant disclosure are by no means restricted thereto. A11 changes, alternations, or modifications conveniently considered by those skilled in the art are deemed to be encompassed within the scope of the instant disclosure delineated by the following claims.

What is claimed is:

1. A single-layer capacitive touch-control panel apparatus, comprising:
a touch-control chip; and
a touch-control substrate, having M touch-control areas which are parallel to a first direction and insulate from each other, wherein M is a positive integer and each touch-control area comprises:
an axial body, electrically connected to the touch-control chip through a first conductive line; and
N electrodes, disposed on the axial body and electrically connected to the touch-control chip through a plurality of second conductive lines, wherein the first conductive lines electrically connected to each touch-control area and the plurality of second conductive lines does not intersect, and the electrodes and the axial body generates effect of mutual capacitance, wherein N is positive integer,
wherein the touch-control chip is disposed on the single-layer touch-control substrate.

2. The single-layer capacitive touch-control panel apparatus according to claim 1, wherein the touch-control chip is disposed on the single-layer touch-control substrate with a substrate technology of the chip on glass.

3. The single-layer capacitive touch-control panel apparatus according to claim 1, wherein the touch-control chip comprises:
a first touch control circuit, electrically connected to the axial bodies through the first conductive lines respectively, and electrically connected to the electrodes of the each of the touch-control areas respectively,
wherein the first touch control circuit sequentially transmits a plurality of the driving scan signal to the axial bodies through the first conductive lines according to a plurality of predetermined scanning time, wherein the plurality of predetermined scanning time are corresponding to the touch-control areas sequentially.

4. The single-layer capacitive touch-control panel apparatus according to claim 3, when voltage of at least one of the electrodes changes, the first touch control circuit acquires a coordinate of at least one touch-point according to voltage variation of each touch-control signal in the second conductive lines and the touch-control areas corresponding to the plurality of predetermined scanning time.

5. The single-layer capacitive touch-control panel apparatus according to claim 3, wherein each axial body comprises:
a first insulating area;
a first conductive area, electrically connected to the first touch control circuit through one of the first conductive lines, the first conductive area receiving one of the driving scan signal; and
a second insulating area, wherein the electrodes of each touch-control area are disposed in the second insulating area, and the electrodes are electrically connected to the first touch control circuit respectively through the plurality of second conductive lines.

6. The single-layer capacitive touch-control panel apparatus according to claim 5, wherein the electrodes and the first conductive area generate mutual capacitance each other.

7. The single-layer capacitive touch-control panel apparatus according to claim 5, wherein a material of the first conductive area and the electrodes is transparent conductive film and a material of the first insulating area and the second insulating area is glass or polyethylene.

8. The single-layer capacitive touch-control panel apparatus according to claim 3, wherein each axial body comprises:
a second conductive area, electrically connected to the first touch control circuit through one of the first conductive lines, second conductive area receiving one of the driving scan signals; and
a third insulating area, wherein the electrodes of each touch-control area are disposed in the third insulating area, and the electrodes are electrically connected to the first touch control circuit respectively through the plurality of second conductive lines.

9. The single-layer capacitive touch-control panel apparatus according to claim 8, wherein a material of the second conductive area and the electrodes is transparent conductive film and a material of the third insulating area is glass or polyethylene.

10. The single-layer capacitive touch-control panel apparatus according to claim 1, wherein a substrate of the touch-control substrate serves as an outer shell protection layer.
